(19) United States
(12) Patent Application Publication
(10) Pub. No.: US 2026/0214847 A1
(43) Pub. Date: Jul. 23, 2026

(54) LIQUID COOLING TUBE, BUSBAR ASSEMBLY AND ELECTRICAL CONNECTION ASSEMBLY

(71) Applicant: Tyco Electronics (Shanghai) Co., Ltd., Shanghai (CN)

(72) Inventors: Jie (Roger) Luo, Foshan (CN); William (Wei) Yao, Kunshan (CN); Rong (Summer) Zhang, Shenzhen (CN); Jiaoyong (Mac) Liu, Shanghai (CN); Hua (Andy) Li, Shanghai (CN)

(73) Assignee: Tyco Electronics (Shanghai) Co., Ltd., Shanghai (CN)

(21) Appl. No.: 19/444,882

(22) Filed: Jan. 9, 2026

(30) Foreign Application Priority Data
Jan. 8, 2025 (CN) 202520044311.1

(51) Int. Cl. H05K 7/20; H02G 5/00; H02G 5/10

(52) U.S. Cl. CPC H05K 7/20272; H02G 5/005; H02G 5/10

(57) ABSTRACT

A liquid cooling tube includes an arc-shaped peripheral wall and a flat bottom wall. The liquid cooling tube is approximately semi-circular in shape such that a cross-section of the liquid cooling tube is approximately semi-circular. When the liquid cooling tube is installed into a slot of a busbar, a heat of the busbar is transferred to a cooling liquid inside the liquid cooling tube through the arc-shaped peripheral wall to cool the busbar.

### CROSS-REFERENCE TO RELATED APPLICATION

This application claims the benefit of the filing date under 35 U.S.C. § 119(a)-(d) of Chinese Patent Application No. 202520044311.1, filed on Jan. 8, 2025.

### FIELD OF THE INVENTION

The present invention relates to a liquid cooling tube and, more particularly, to a liquid cooling tube, a busbar assembly comprising the liquid cooling tube, and an electrical connection assembly comprising the busbar assembly.

### BACKGROUND OF THE INVENTION

In order to electrically connect busbars in two cabinets, a horizontal busbar connection assembly needs to be provided. The existing busbar connection assembly usually includes a positive busbar and a negative busbar. The two ends of the positive busbar are electrically connected to the positive bars in two cabinets, and the two ends of the negative busbar are electrically connected to the negative bars in two cabinets. In order to carry a current of over 3000A, the existing busbar has a large cross-sectional area, which makes it difficult to assemble and maintain the busbar connection assembly, resulting in high costs.

### SUMMARY OF THE INVENTION

A liquid cooling tube includes an arc-shaped peripheral wall and a flat bottom wall. The liquid cooling tube is approximately semi-circular in shape such that a cross-section of the liquid cooling tube is approximately semi-circular. When the liquid cooling tube is installed into a slot of a busbar, a heat of the busbar is transferred to a cooling liquid inside the liquid cooling tube through the arc-shaped peripheral wall to cool the busbar.

### BRIEF DESCRIPTION OF DRAWINGS

The invention will now be described by way of example with reference to the accompanying figures, of which:

FIG. 1 is a perspective view of a liquid cooling system according to an exemplary embodiment;

FIG. 2 is a partial exploded view of the liquid cooling system of FIG. 1;

FIG. 3 is a transverse sectional view of a liquid cooling tube of the liquid cooling system of FIG. 1;

FIG. 4 is a perspective assembly view of a busbar and an electric insulating isolation plate according to an exemplary embodiment;

FIG. 5 is a transverse sectional view of the busbar of FIG. 4 and the electric insulating isolation plate of FIG. 4;

FIG. 6 is a perspective view of an electrical connection assembly according to an exemplary embodiment;

FIG. 7 is a transverse sectional view of the electrical connection assembly of FIG. 6; and

FIG. 8 is an enlarged view of a portion of FIG. 7.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

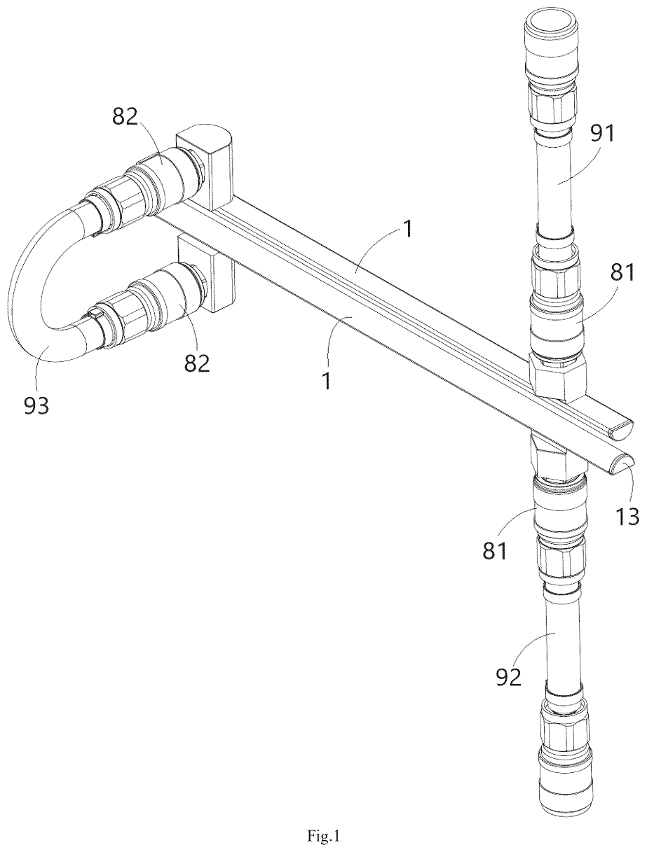

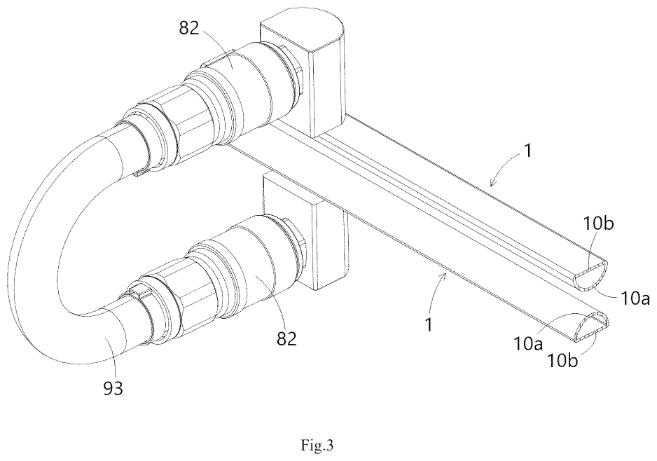

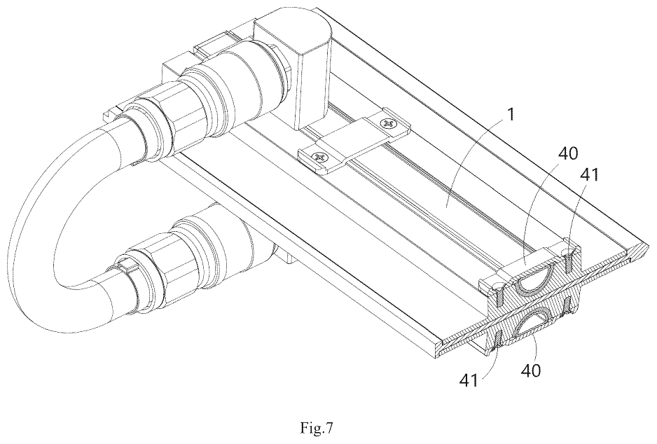

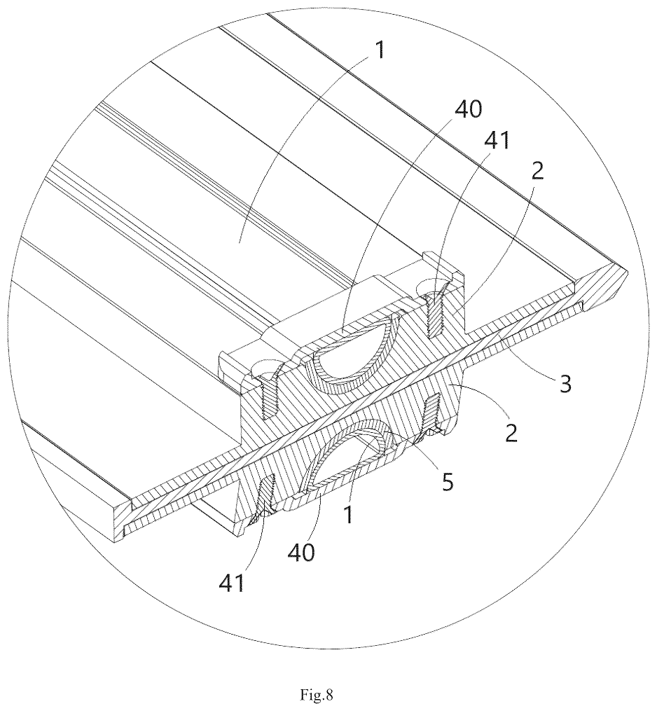

An exemplary embodiment of a liquid cooling tube 1 will now be described with reference to FIGS. 1-8. As shown in FIGS. 7-8, the liquid cooling tube 1 is suitable for installation into a slot 20 of a busbar 2. As shown in FIG. 3, the liquid cooling tube 1 is approximately semi-circular in shape, with an arc-shaped peripheral wall 10a and a flat bottom wall 10b, resulting in a semi-circular cross-section of the liquid cooling tube 1. When the liquid cooling tube 1 is installed into the slot 20 of the busbar 2, the heat of the busbar 2 is transferred to a cooling liquid inside the liquid cooling tube 1 through the arc-shaped peripheral wall 10a of the liquid cooling tube 1 to cool the busbar 2.

As shown in FIGS. 1-3 and 6-8, the liquid cooling tube 1 is approximately semi-circular in shape. For example, the liquid cooling tube 1 may be semi-circular or elliptical in shape. As a further example, the liquid cooling tube 1 may be in a semi-cylindrical shape or a semi-elliptical cylindrical shape. The arc-shaped peripheral wall 10a of the liquid cooling tube 1 can increase the thermal conductivity area, thereby improving the heat dissipation efficiency. The liquid cooling tube 1 can be an integral part, such as an integral cast part or an integral machined part. However, the present invention is not limited to the illustrated embodiments; for example, the liquid cooling tube 1 may also be a multi-stage welded tube.

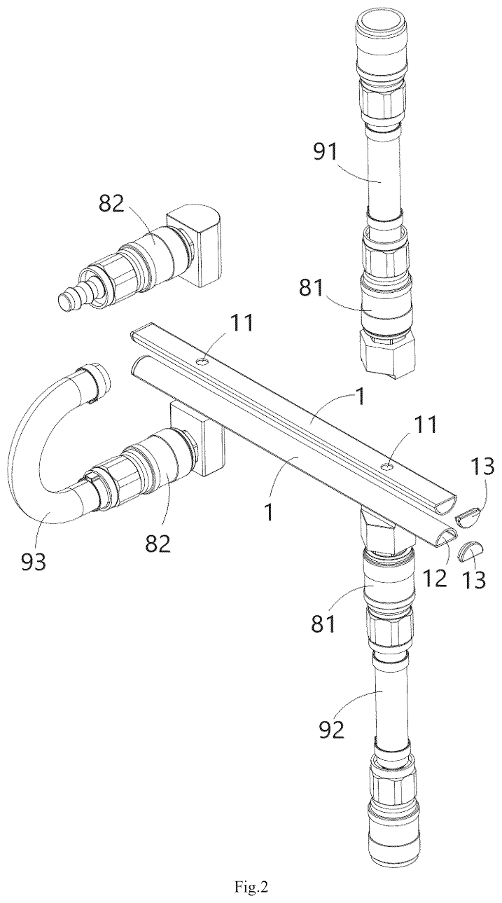

As shown in FIG. 2, two openings 11 are formed on the flat bottom wall 10b of the liquid cooling tube 1, which are connected to the inner cavity of the liquid cooling tube 1. The two openings 11 are respectively located near the two ends of the liquid cooling tube 1. When cooling the busbar 2, the cooling liquid flows in from one of the two openings 11 of liquid cooling tube 1 and flows out from the other of the two openings 11 of liquid cooling tube 1.

As shown in FIG. 2, the liquid cooling tube 1 has two open end ports 12. When in use, the two open end ports 12 of the liquid cooling tube 1 are suitable for being sealed with sealing end caps 13, as shown in FIG. 1-2, inserted separately. However, the present invention is not limited to the illustrated embodiments; for example, the liquid cooling tube 1 may have closed ends, which eliminates the need for the sealing end caps 13.

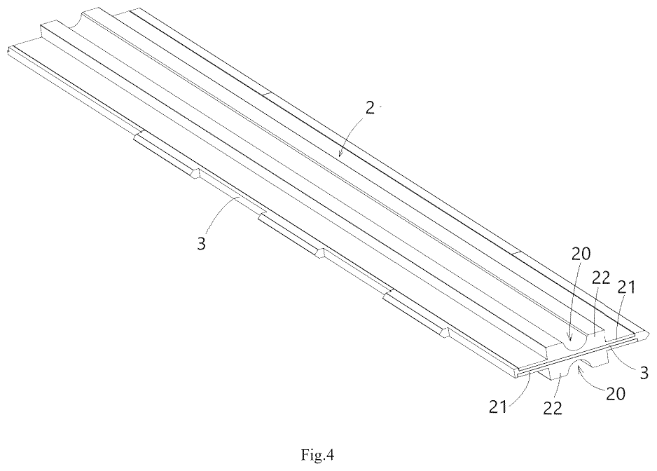

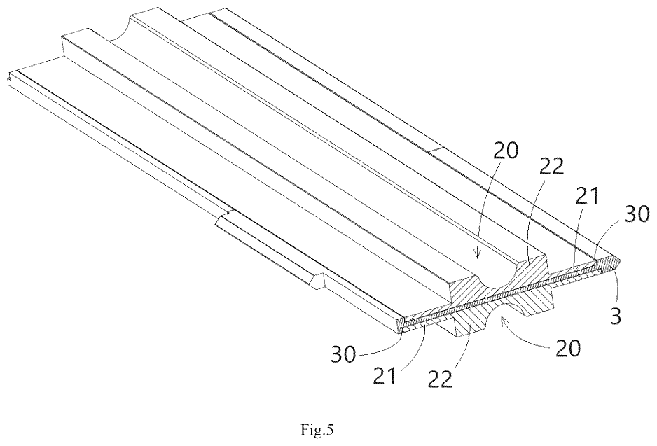

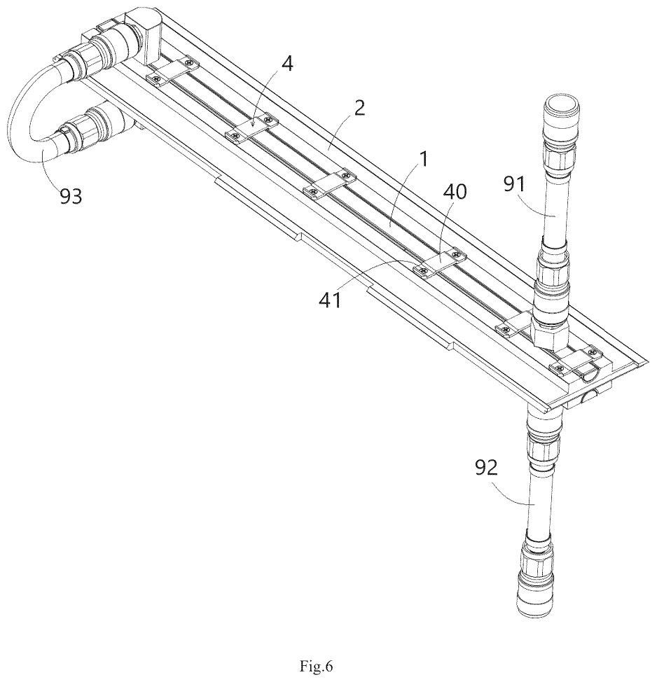

An exemplary embodiment of a busbar assembly will now be described with reference to FIGS. 1-8. The busbar assembly includes a busbar 2, as shown in FIGS. 4, 6, and 8, and the aforementioned liquid cooling tube 1, as shown in FIGS. 1-3 and 6-8. The busbar 2 is formed with a slot 20, as shown in FIGS. 4-5, extending along its length direction. The cross-section of slot 20 is semi-circular. The liquid cooling tube 1 is accommodated in the slot 20 of the busbar 2, as shown in FIGS. 6-8. The arc-shaped peripheral wall 10a of the liquid cooling tube 1 faces the inner surface of the slot 20 of the busbar 2, so that the heat of the busbar 2 can be transferred to the cooling liquid inside the liquid cooling tube 1 through the arc-shaped peripheral wall 10a of the liquid cooling tube 1 to cool the busbar 2.

As shown in FIGS. 4-5, the busbar 2 includes a flat base plate 21 and a strip-shaped protrusion 22 formed on one side of the flat base plate 21. The aforementioned slot 20 is formed on the strip-shaped protrusion 22. The busbar 2 can be an integral part. For example, the busbar 2 can be an integral stamped part or an integral machined part.

The liquid cooling tube 1 is made of an electric conductive material; for example, the liquid cooling tube 1 can be made of aluminum, aluminum alloy, copper, or copper alloy. As shown in FIG. 8, an electric insulation thermal conductive pad 5 is provided between the arc-shaped peripheral wall 10a of the liquid cooling tube 1 and the inner surface of the slot 20 of the busbar 2. The electric insulation thermal conductive pad 5 is compressed between the arc-shaped peripheral wall 10a of the liquid cooling tube 1 and the inner surface of the slot 20 of the busbar 2, and is used to transfer the heat of the busbar 2 to the liquid cooling tube 1 and electrically isolate the busbar 2 from the liquid cooling tube 1.

In another exemplary embodiment of the present invention, the liquid cooling tube 1 is made of an electric conductive material; for example, the liquid cooling tube 1 may be made of aluminum, aluminum alloy, copper, or copper alloy. An electric insulation thermal conductive layer is formed onto the outer surface of the arc-shaped peripheral wall 10a of the liquid cooling tube 1 or the inner surface of the slot 20 of the busbar 2. The electric insulation thermal conductive layer is used to transfer the heat of the busbar 2 to the liquid cooling tube 1 and electrically isolate the busbar 2 from the liquid cooling tube 1.

In another exemplary embodiment of the present invention, the liquid cooling tube 1 is made of an electric conductive material; for example, the liquid cooling tube 1 may be made of aluminum, aluminum alloy, copper, or copper alloy. An electric insulation thermal conductive film is attached to the outer surface of the arc-shaped peripheral wall 10a of the liquid cooling tube 1 or the inner surface of the slot 20 of the busbar 2. This electric insulation thermal conductive film is used to transfer the heat from the busbar 2 to the liquid cooling tube 1 and electrically isolate the busbar 2 from the liquid cooling tube 1.

In another exemplary embodiment of the present invention, the liquid cooling tube 1 may be made of an electric insulation material, such as plastic. The arc-shaped peripheral wall 10a of the liquid cooling tube 1 can be in direct thermal contact with the inner surface of the slot 20 of the busbar 2 or can be adhered to the inner surface of the slot 20 of the busbar 2 through thermal conductive adhesive.

As shown in FIG. 6, the busbar assembly further includes multiple pressing devices 4. The multiple pressing devices 4 are installed on the busbar 2 to press the liquid cooling tube 1 into the slot 20 of the busbar 2, ensuring reliable thermal contact between the electric insulation thermal conductive pad 5 and the inner surface of the slot 20 of the busbar 2, as well as ensuring reliable thermal contact between the electric insulation thermal conductive pad 5 and the outer surface of the arc-shaped peripheral wall 10a of the liquid cooling tube 1.

As shown in FIG. 6, the multiple pressing devices 4 are arranged in a row along the length direction of the busbar 2. As shown in FIGS. 6-8, the pressing device 4 includes an electric insulation pressing plate 40 and two screws 41. The electric insulation pressing plate 40 spans across the liquid cooling tube 1. The two screws 41 fasten the two ends of the electric insulation pressing plate 40 to the busbar 2 respectively. The electric insulation pressing plate 40 applies a predetermined pressing force on the flat bottom wall 10b of the liquid cooling tube 1.

An exemplary embodiment of an electrical connection assembly will now be described with reference to FIGS. 1-8. The electrical connection assembly includes two busbar assemblies and an electric insulating isolation plate 3, as shown in FIGS. 4-5 and 8. The electric insulating isolation plate 3 is clamped between the busbars 2 of the two busbar assemblies to electrically isolate the busbars 2 of the two busbar assemblies. The busbar 2 has a first side and a second side that are opposite in its thickness direction. The first side of the busbar 2 is attached to the electric insulating isolation plate 3, and the liquid cooling tube 1 is located on the second side of the busbar 2.

As shown in FIG. 5, the electric insulating isolation plate 3 has two opposite sides in its thickness direction, and installation grooves 30 are respectively formed on both sides of the electric insulating isolation plate 3. The busbars 2 of the two busbar assemblies are respectively installed and positioned in the installation grooves 30 on both sides of the electric insulating isolation plate 3. Fixing components or structures can also be used to fix the busbars 2 of the two busbar assemblies to the electric insulating isolation plate 3. For example, an elastic buckle can be formed on the edge of the installation groove 30 of the electric insulating isolation plate 3, and the busbar 2 can be fixed to the installation groove 30 of the electric insulating isolation plate 3 using the elastic buckle.

As shown in FIGS. 1-2 and 6, the electrical connection assembly further includes a liquid inlet pipe 91, a liquid outlet pipe 92, and a connecting pipe 93. The liquid inlet pipe 91 is connected to the opening 11 at one end of the liquid cooling tube 1 of one of the two busbar assemblies. As shown in FIG. 1, the liquid outlet pipe 92 is connected to the opening 11 at one end of the liquid cooling tube 1 of the other of the two busbar assemblies. As further shown in FIG. 1, the two ends of the connecting pipe 93 are respectively connected to the openings 11 at the other ends of the liquid cooling tubes 1 of the two busbar assemblies, and used to interconnect the liquid cooling tubes 1 of the two busbar assemblies.

As shown in FIGS. 1-2, the electrical connection assembly further includes two first pipe joints 81 and two second pipe joints 82. As shown in FIG. 1, the two first pipe joints 81 are respectively connected to the openings 11 at one ends of the liquid cooling tubes 1 of the two busbar assemblies. As further shown in FIG. 1, the two second pipe joints 82 are respectively connected to the openings 11 at the other ends of the liquid cooling tubes 1 of the two busbar assemblies. The liquid inlet pipe 91 is detachably connected to the first pipe joint 81 of the liquid cooling tube 1 of one of the two busbar assemblies. The liquid outlet pipe 92 is detachably connected to the first pipe joint 81 of the liquid cooling tube 1 of the other of the two busbar assemblies. The two ends of the connecting pipe 93 are respectively detachably connected to the second pipe joints 82 of the liquid cooling tubes 1 of the two busbar assemblies.

As shown in FIGS. 1-2, the two liquid cooling tubes 1, the liquid inlet pipe 91, the liquid outlet pipe 92, the connecting pipe 93, the two first pipe joints 81, and the two second pipe joints 82 constitute the liquid cooling system of the electrical connection assembly, which is used to cool the two busbars 2.

Two ends of the busbar 2 of one of the two busbar assemblies are used to electrically connect to two positive busbars respectively, while two ends of the busbar 2 of the other of the two busbar assemblies are used to electrically connect to two negative busbars respectively. In the illustrated embodiment, when a large current passes through the busbar 2, the heat generated by the busbar 2 is promptly transferred to the cooling liquid inside the liquid cooling tube 1, effectively preventing an excessive temperature rise of the busbar 2.

In the aforementioned exemplary embodiments according to the present invention, the liquid cooling tube 1 can cool the busbar 2, and therefore, the present invention can improve the current carrying capacity of the busbar 2 without increasing the cross-sectional size of the busbar 2. In addition, in the present invention, the cross-section of the liquid cooling tube 1 is approximately semi-circular, which can improve the cooling efficiency of the liquid cooling tube 1.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A liquid cooling tube, comprising:
an arc-shaped peripheral wall; and
a flat bottom wall, the liquid cooling tube is approximately semi-circular in shape such that a cross-section of the liquid cooling tube is approximately semi-circular, and when the liquid cooling tube is installed into a slot of a busbar, a heat of the busbar is transferred to a cooling liquid inside the liquid cooling tube through the arc-shaped peripheral wall to cool the busbar.

2. The liquid cooling tube of claim 1, wherein the liquid cooling tube is in a semi-cylindrical shape or a semi-elliptical cylindrical shape.

3. The liquid cooling tube of claim 1, wherein the liquid cooling tube is an integral part.

4. The liquid cooling tube of claim 1, wherein a pair of openings are formed on the flat bottom wall, the openings are in communication with an inner cavity of the liquid cooling tube, the openings are respectively located adjacent to a pair of ends of the liquid cooling tube, and when cooling the busbar, the cooling liquid flows in from one of the openings and flows out from another of the openings.

5. The liquid cooling tube of claim 1, wherein the liquid cooling tube has a pair of closed ends.

6. The liquid cooling tube of claim 1, wherein the liquid cooling tube has a pair of open end ports, each open end port is sealed by one sealing end cap.

7. A busbar assembly, comprising:
a busbar having a slot extending along a length direction of the busbar, the slot has a semi-circular cross-section; and
a liquid cooling tube including an arc-shaped peripheral wall and a flat bottom wall, the liquid cooling tube is approximately semi-circular in shape such that a cross-section of the liquid cooling tube is approximately semi-circular, and when the liquid cooling tube is installed into the slot of the busbar, the arc-shaped peripheral wall faces an inner surface of the slot of the busbar, such that a heat of the busbar is transferred to a cooling liquid inside the liquid cooling tube through the arc-shaped peripheral wall to cool the busbar.

8. The busbar assembly of claim 7, wherein the busbar has a flat base plate and a strip-shaped protrusion formed on one side of the flat base plate, the slot is formed on the strip-shaped protrusion.

9. The busbar assembly of claim 8, wherein the busbar is an integral part.

10. The busbar assembly of claim 7, wherein the liquid cooling tube is made of an electrically conductive material, an electric insulation thermal conductive pad is provided between the arc-shaped peripheral wall and the inner surface of the slot of the busbar, the electric insulation thermal conductive pad transfers the heat of the busbar to the liquid cooling tube and electrically isolates the busbar from the liquid cooling tube.

11. The busbar assembly of claim 7, wherein the liquid cooling tube is made of an electrically conductive material, an electric insulation thermal conductive layer is formed on an outer surface of the arc-shaped peripheral wall or the inner surface of the slot of the busbar, the electric insulation thermal conductive layer transfers the heat of the busbar to the liquid cooling tube and electrically isolates the busbar from the liquid cooling tube.

12. The busbar assembly of claim 7, wherein the liquid cooling tube is made of an electrically conductive material, an electric insulation thermal conductive film is attached to an outer surface of the arc-shaped peripheral wall or the inner surface of the slot of the busbar, the electric insulation thermal conductive film transfers the heat of the busbar to the liquid cooling tube and electrically isolates the busbar from the liquid cooling tube.

13. The busbar assembly of claim 7, wherein the liquid cooling tube is made of an electrically insulative material, the arc-shaped peripheral wall is in direct thermal contact with the inner surface of the slot of the busbar or bonded to the inner surface of the slot of the busbar through a thermal conductive adhesive.

14. The busbar assembly of claim 7, further comprising a plurality of pressing devices each installed on the busbar and pressing the liquid cooling tube into the slot of the busbar.

15. The busbar assembly of claim 14, wherein the plurality of pressing devices are arranged in a row along the length direction of the busbar, each pressing device includes an electric insulation pressing plate and a pair of screws, the electric insulation pressing plate spans across the liquid cooling tube, the screws are used to respectively fasten a pair of ends of the electric insulation pressing plate to the busbar, the electric insulation pressing plate applies a predetermined pressing force on the flat bottom wall of the liquid cooling tube.

16. An electrical connection assembly, comprising:
a pair of busbar assemblies, each busbar assembly includes a busbar and a liquid cooling tube, the busbar is formed with a slot extending along a length direction of the busbar and has a semi-circular cross-section, the liquid cooling tube includes an arc-shaped peripheral wall and a flat bottom wall, the liquid cooling tube is approximately semi-circular in shape such that a cross-section of the liquid cooling tube is approximately semi-circular, when the liquid cooling tube is installed into the slot of the busbar, the arc-shaped peripheral wall faces an inner surface of the slot of the busbar, such that a heat of the busbar is transferred to a cooling liquid inside the liquid cooling tube through the arc-shaped peripheral wall to cool the busbar; and
an electric insulating isolation plate clamped between each busbar of the pair of busbar assemblies to electrically isolate each busbar of the pair of busbar assemblies, each busbar has a first side and a second side opposite to each other in a thickness direction of the busbar, the first side of each busbar is attached to the electric insulating isolation plate, and one liquid cooling tube is located on the second side of each busbar.

17. The electrical connection assembly of claim 16, wherein the electric insulating isolation plate has a pair of opposite sides in a thickness direction of the electric insulating isolation plate, a plurality of installation grooves are formed on both of the pair of opposite sides of the electric insulating isolation plate, the busbars of the pair of busbar assemblies are respectively installed and positioned in the installation grooves.

18. The electrical connection assembly of claim 16, further comprising a liquid inlet pipe, a liquid outlet pipe, and a connecting pipe, the liquid inlet pipe is connected to an opening at one end of the liquid cooling tube of one of the pair of busbar assemblies, the liquid outlet pipe is connected to an opening at one end of the liquid cooling tube of another of the pair of busbar assemblies, both ends of the connecting pipe are respectively connected to openings at other ends of the liquid cooling tubes of the pair of busbar assemblies, the connecting pipe interconnects the liquid cooling tubes of the pair of busbar assemblies.

19. The electrical connection assembly of claim 18, further comprising a pair of first pipe joints and pair of second pipe joints, each first pipe joint is connected to the opening at one end of one of the liquid cooling tubes of the pair of busbar assemblies, each second pipe joint is connected to the opening at another end of one of the liquid cooling tubes of the pair of busbar assemblies, the liquid inlet pipe is detachably connected to the first pipe joint of the liquid cooling tube of one of the pair of busbar assemblies, the liquid outlet pipe is detachably connected to the first pipe joint of the liquid cooling tube of the other of the pair of busbar assemblies, and a pair of ends of the connecting pipe are respectively detachably connected to the second pipe joints of the liquid cooling tubes of the pair of busbar assemblies.

20. The electrical connection assembly of claim 16, wherein a pair of ends of the busbar of one of the pair of busbar assemblies are respectively used to electrically connect to a pair of positive busbars, and a pair of ends of the busbar of the other of the pair of busbar assemblies are used to respectively electrically connect to a pair of negative busbars.
